(19) United States
(12) Patent Application Publication
(10) Pub. No.: US 2024/0071877 A1
(43) Pub. Date: Feb. 29, 2024

(54) SEMICONDUCTOR DEVICE

(71) Applicant: ROHM CO., LTD., Kyoto-shi (JP)

(72) Inventors: Yosui FUTAMURA, Kyoto-shi (JP); Shunya MIKAMI, Kyoto-shi (JP); Ryuta KIMURA, Kyoto-shi (JP); Kazuhisa KUMAGAI, Kyoto-shi (JP)

(21) Appl. No.: 18/502,759

(22) Filed: Nov. 6, 2023

Related U.S. Application Data
(63) Continuation of application No. PCT/JP2022/019611, filed on May 9, 2022.

(30) Foreign Application Priority Data
May 18, 2021 (JP) 2021-083764

(51) Int. Cl. H01L 23/495; H01L 21/48; H01L 21/56; H01L 23/31

(52) U.S. Cl. CPC H01L 23/49568; H01L 21/4825; H01L 21/565; H01L 23/3107; H01L 23/4952; H01L 23/49562; H01L 23/49575

(57) ABSTRACT

A semiconductor device includes a first semiconductor element, a first object, a sealing resin and a covering part. The first semiconductor element includes a first electrode. The first object includes a first surface facing the first electrode. The sealing resin covers the first semiconductor element and the first object. The covering part is interposed between the first electrode and the first surface and contains a material having a higher thermal conductivity than the sealing resin.

### TECHNICAL FIELD

The present disclosure relates to semiconductor devices.

### BACKGROUND ART

Switching elements are used for current control in various industrial devices and automobiles. JP-A-2019-212930 discloses an example of a conventional switching element. In a switching element, energy is generated by an electromotive force that is induced when the current is turned off. Active clamping is a function to absorb the energy by the switching element.

### BRIEF DESCRIPTION OF THE DRAWINGS

FIG. 1 is a plan view of a semiconductor device according to a first embodiment of the present disclosure.

FIG. 2 is a fragmentary plan view of the semiconductor device according to the first embodiment of the present disclosure.

FIG. 3 is a sectional view taken along line III-III in FIG. 2.

FIG. 4 is an enlarged fragmentary sectional view of the semiconductor device according to the first embodiment of the present disclosure.

FIG. 5 is a sectional view taken along line V-V in FIG. 2.

FIG. 6 is a fragmentary sectional view showing a method of manufacturing a semiconductor device according to the first embodiment of the present disclosure.

FIG. 7 is a fragmentary sectional view showing the method of manufacturing a semiconductor device according to the first embodiment of the present disclosure.

FIG. 8 is a fragmentary sectional view showing another method of manufacturing a semiconductor device according to the first embodiment of the present disclosure.

FIG. 9 is a fragmentary sectional view showing yet another method of manufacturing a semiconductor device according to the first embodiment of the present disclosure.

FIG. 10 is a sectional view of a semiconductor device according to a first variation of the first embodiment of the present disclosure.

FIG. 11 is an enlarged fragmentary sectional view of the semiconductor device according to the first variation of the first embodiment of the present disclosure.

FIG. 12 is a sectional view showing a method of manufacturing a semiconductor device according to the first variation of the first embodiment of the present disclosure.

FIG. 13 is a fragmentary plan view of a semiconductor device according to a second embodiment of the present disclosure.

FIG. 14 is a sectional view taken along line XIV-XIV in FIG. 13.

FIG. 15 is an enlarged fragmentary sectional view of a semiconductor device according to the second embodiment of the present disclosure.

FIG. 16 is a sectional view taken along line XVI-XVI in FIG. 13.

FIG. 17 is an enlarged fragmentary sectional view showing a method of manufacturing a semiconductor device according to the second embodiment of the present disclosure.

FIG. 18 is an enlarged fragmentary sectional view showing a method of manufacturing a semiconductor device according to the second embodiment of the present disclosure.

FIG. 19 is a fragmentary plan view of a semiconductor device according to a third embodiment of the present disclosure.

FIG. 20 is a sectional view taken along line XX-XX in FIG. 19.

FIG. 21 is a sectional view taken along line XXI-XXI in FIG. 19.

FIG. 22 is a sectional view of a semiconductor device according to a first variation of the third embodiment of the present disclosure.

FIG. 23 is a sectional view of a semiconductor device according to the first variation of the third embodiment of the present disclosure.

FIG. 24 is a sectional view of a semiconductor device according to a fourth embodiment of the present disclosure.

FIG. 25 is a sectional view of a semiconductor device according to the fourth embodiment of the present disclosure.

FIG. 26 is a sectional view of a semiconductor device according to a first variation of the fourth embodiment of the present disclosure.

FIG. 27 is a sectional view of the semiconductor device according to the first variation of the fourth embodiment of the present disclosure.

### DETAILED DESCRIPTION OF EMBODIMENTS

The following describes preferred embodiments of the present disclosure in detail with reference to the drawings.

In the present disclosure, terms such as “first”, “second”, “third” and so on are used merely as labels and not intended to impose ordinal requirements on the items referred to by these terms.

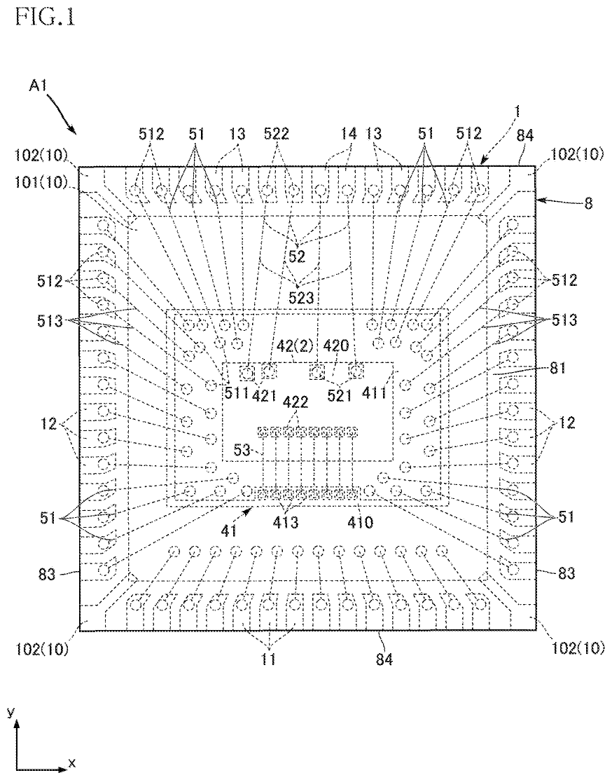

FIGS. 1 to 5 show a semiconductor device A1 according to a first embodiment of the present disclosure. The semiconductor device A1 of the present embodiment includes a plurality of leads 1, a first object 2, a first semiconductor element 41, a plurality of first wires 51, a plurality of second wires 52, a plurality of third wires 53 and a plurality of fourth wires 54. The size and shape of the semiconductor device A1 are not specifically limited. In one example, the size of the semiconductor device A1 is about 4 to 7 mm in the x direction, about 4 to 8 mm in the y direction, and about 0.7 to 2.0 mm in the z direction.

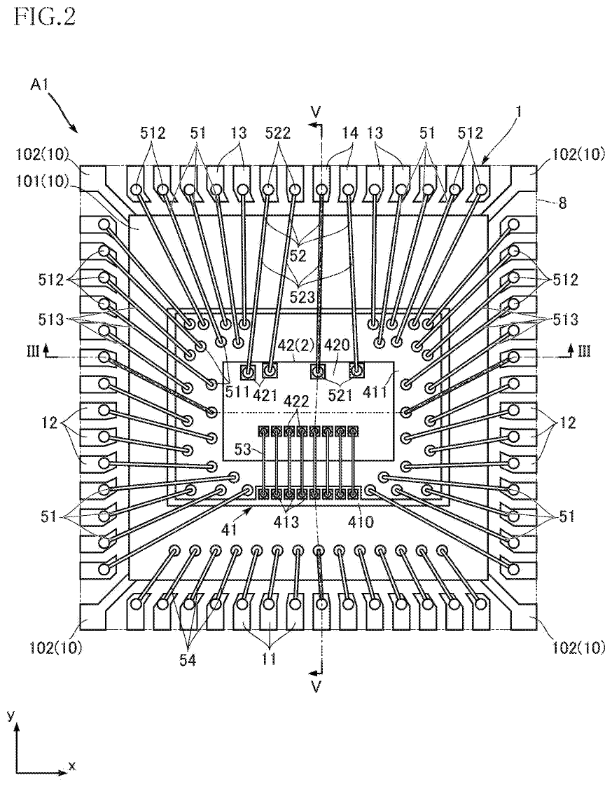

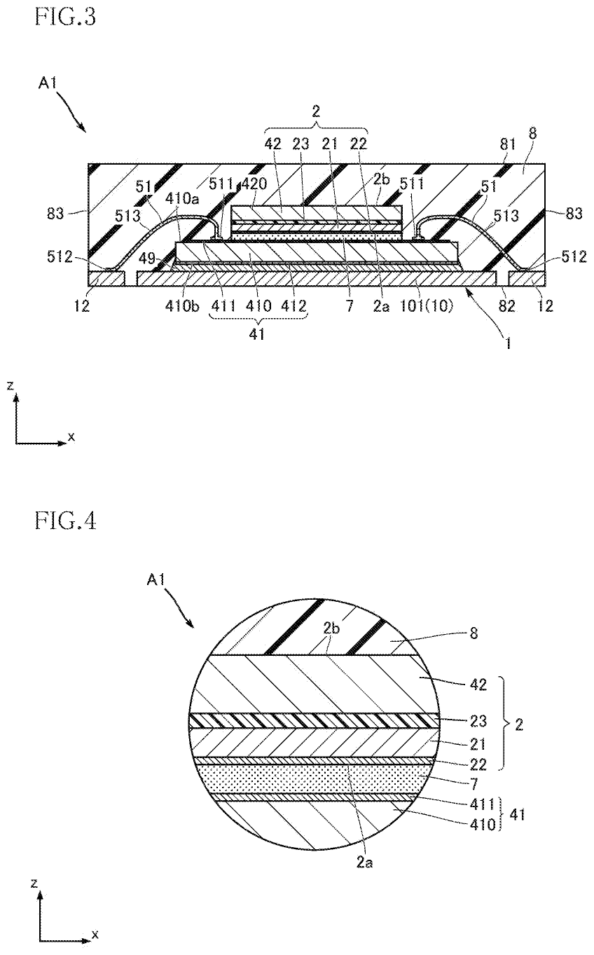

FIG. 1 is a plan view of the semiconductor device A1. FIG. 2 is a fragmentary plan view of the semiconductor device A1. FIG. 3 is a sectional view taken along line III-III in FIG. 2. FIG. 4 is an enlarged fragmentary sectional view of the semiconductor device A1. FIG. 5 is a sectional view taken along line V-V in FIG. 2. For the convenience of description, FIG. 2 shows a sealing resin 8 with imaginary lines.

The leads 1 support the first semiconductor element 41 and form conduction paths to the first semiconductor element 41. The configuration and material of the leads 1 are not specifically limited. The leads 1 may be made of a metal, typical examples of which include Cu, Ni, Fe and alloys of these metals. Appropriate portions of the leads 1 may be plated with a metal, typically Ag, Ni, Pd or Au, for example. The thickness of the leads 1 are not specifically limited and may be about 0.12 to 0.2 mm, for example.

In the present embodiment, the leads 1 include a lead 10, a plurality of leads 11, a plurality of leads 12, a plurality of leads 13 and a plurality of leads 14.

The lead 10 includes a die pad 101 and four corner parts 102.

The die pad 101 is a portion that supports the first semiconductor element 41. The shape of the die pad 101 is not specifically limited. In the present embodiment, the die pad 101 is rectangular as viewed in the z direction (or synonymously “in plan view”).

The four corner parts 102 extend radially from the four corners of the die pad 101. In the present embodiment, each corner part 102 includes a strip portion extending from the die pad 101 and a rectangular portion connected to the strip part.

The leads 11 are spaced apart from the die pad 101 in a first sense of the y direction and form conduction paths to the first semiconductor element 41. The leads 11 are arranged side by side in the x direction, together with two of the corner parts 102 that are spaced apart in the x direction.

The leads 12 are located on either side of the die pad 101 in the x direction and spaced apart from the die pad 101 in the x direction. The leads 12 form conduction paths to the first semiconductor element 41. On either side of the die pad 101 in the x direction, the leads 12 are arranged side by side in the y direction, together with two of the corner parts 102 spaced apart in the y direction.

The leads 13 are spaced apart from the die pad 101 in a second sense of the y direction and form conduction paths to the first semiconductor element 41. The leads 13 are arranged side by side in the x direction, together with two of the corner parts 102 that are spaced apart in the x direction.

The leads 14 are spaced apart from the die pad 101 in the second sense of the y direction and form conduction paths to a second semiconductor element 42 of the first object 2 described later. The leads 14 are arranged side by side in the x direction, together with the leads 13 and two of the corner parts 102 spaced apart in the x direction. The leads 14 are located in the central region between the leads 13 in the x direction.

The first semiconductor element 41 is a component that enables the electrical function of the semiconductor device A1. In the present embodiment, the first semiconductor element 41 enables a switching function. The first semiconductor element 41 includes an element body 410, a first electrode 411, a second electrode 412 and a plurality of third electrodes 413. The thickness of the first semiconductor element 41 in the z direction is at least 100 μm and at most 200 μm, for example.

The configuration of the first semiconductor element 41 is not specifically limited. For example, the first semiconductor element 41 may include a functional layer forming a transistor and may further include a control part. Depending on the configuration, the first semiconductor element 41 can include, or not include, appropriate numbers of the second electrodes 412 and the third electrodes 413. In addition to the first semiconductor element 41, one or more other semiconductor elements can be mounted on the die pad 101. The functions of such other semiconductor elements are not specifically limited.

The element body 410 has an element obverse surface 410a and an element reverse surface 410b. The element obverse surface 410a faces in a first sense of the z direction. The element reverse surface 410b faces away from the element obverse surface 410a in the z direction. The material of the element body 410 is not specifically limited. The element body 410 may be made of a semiconductor material, such as Si, SiC or GaN, for example.

The element body 410 includes a functional layer (not shown), for example. The functional layer forms a transistor structure, typically a metal-oxide-semiconductor field-effect transistor (MOSFET) or a metal-insulator-semiconductor field-effect transistor (MOSFET).

The first electrode 411 is disposed on the element obverse surface 410a of the element body 410. The shape and size of the first electrode 411 are not specifically limited. In the illustrated example, the first electrode 411 covers most of the element obverse surface 410a. The first electrode 411 has a recess that is recessed from the side in the first sense of the y direction. As viewed in the z direction, the first electrode 411 overlaps with the functional layer 408. In the present embodiment, the first electrode 411 is a source electrode. The material of the first electrode 411 is not specifically limited, and typical examples of the material include metals, such as aluminum (Al), Al—Si and copper (Cu), and alloys of such metals. The first electrode 411 may be a laminate of layers of a plurality of metals selected from these examples.

The second electrode 412 is disposed on the element reverse surface 410b of the element body 410. In the present embodiment, the second electrode 412 covers the entire element reverse surface 410b. In the present embodiment, the second electrode 412 is a drain electrode. The material of the second electrode 412 is not specifically limited, and typical examples of the material include metals, such as aluminum (Al), Al—Si and copper (Cu), and alloys of such metals. The second electrode 412 may be a laminate of layers of a plurality of metals selected from these examples.

The third electrodes 413 are disposed on the element obverse surface 410a. In the illustrated example, the third electrodes 413 are located in a portion of the element obverse surface 410a that is closer to the leads 11 in the y direction (in the first sense of the y direction). The third electrodes 413 are accommodated in the recess of the first electrode 411. The function and the number of the third electrodes 413 are not specifically limited. The third electrodes 413 of the present embodiment include a gate electrode. The third electrodes 413 also include a source sense electrode, a temperature sense electrode and a current monitor terminal, for example.

The first semiconductor element 41 is mounted on the die pad 101 of the lead 10. In the present embodiment, the second electrode 412 of the first semiconductor element 41 is electrically bonded to the die pad 101 via a bonding material 49. The bonding material 49 is not specifically limited and may be a conductive bonding material, such as Ag paste.

The first object 2 is disposed to face the first electrode 411 of the first semiconductor element 41 in the z direction. The first object 2 has a first surface 2a and a second surface 2b. The first surface 2a faces the first electrode 411. The second surface 2b faces away from the first surface 2a. The first surface 2a is in contact with a covering part 7. In the present embodiment, the first surface 2a is a flat surface extending along the x-y plane.

The configuration of the first object 2 is not specifically limited. The first object 2 may include a semiconductor element that performs an electrical function or include a passive component. Alternatively, the first object 2 may include at least one of an insulating member or a metal member. In the present embodiment, the first object 2 includes a second semiconductor element 42, a bonding layer 23, an insulating layer 21 and a metal layer 22. As shown in FIG. 2, the first object 2 of the present embodiment is smaller than the first electrode 411 as viewed in the z direction.

The second semiconductor element 42 is a component that functions to control the first semiconductor element 41, such as a current sensor circuit, a temperature sensor circuit, an overcurrent protection circuit, an heating protection circuit and an undervoltage lockout circuit, for example. The second semiconductor element 42 includes an element body 420 and a plurality of electrodes 421 and a plurality of electrodes 422. The thickness of the second semiconductor element 42 in the z direction is at least 100 μm and at most 300 μm, for example.

The element body 420 is made of Si, for example, and forms a control circuit for controlling the first semiconductor element 41. In the present embodiment, one surface of the element body 420 in the z direction forms the second surface 2b.

The electrodes 421 are offset toward the end of the element body 420 in the second sense of the y direction and are substantially aligned in the x direction.

The electrodes 422 are offset toward the end of the element body 420 in the first sense of the y direction and are aligned in the x direction.

The bonding layer 23 bonds the second semiconductor element 42 and the insulating layer 21. The configuration of the bonding layer 23 is not specifically limited. The bonding layer 23 may be made of an insulating bonding material or a bonding tape, such as a dicing die attach film (DAF).

The insulating layer 21 insulates the covering part 7 and the second semiconductor element 42. The configuration of the insulating layer 21 is not specifically limited. In the illustrated example, the insulating layer 21 is a plate-like member containing an insulating material. Examples of the insulating material contained in the insulating layer 21 include ceramic materials, such as alumina and aluminum nitride, and Si. The thickness of the insulating layer 21 in the z direction is at least 100 μm and at most 200 μm, for example. The shape and size of the insulating layer 21 are not specifically limited. In the illustrated example, the insulating layer 21 has the same (or substantially the same) rectangular shape and size as the second semiconductor element 42 as viewed in the z direction.

The metal layer 22 is disposed on one surface of the insulating layer 21 in the z direction, forming the first surface 2a facing the first electrode 411. The metal layer 22 serves to strengthen the bond to the covering part 7 and contains a metal, such as Ag, Cu or Al, for example. When the insulating layer 21 can be bonded to the covering part 7 with a sufficient bond strength, the metal layer 22 of the first object 2 may be omitted.

The first wires 51 are used to provide electrical connections between the first electrodes 411 of the first semiconductor element 41 and the leads 11, 12 and 13. The material of the first wires 51 is not specifically limited. For example, the first wires 51 are made of a metal, typically Au, Cu or Al. As shown in FIGS. 2 and 3, each first wire 51 of the present embodiment includes a bonding part 511, a bonding part 512 and a loop part 513. The configuration of the first wires 51 is not specifically limited. In the illustrated example, the first wires 51 are made of a material containing Cu and formed by a capillary, for example. In the present embodiment, the first wires 51 conducts the current that is switched on and off by the first semiconductor element 41.

The semiconductor device according to the present disclosure is not limited to the configuration in which the first wires 51 are bonded to the first electrode 411. For example, other than the first wires 51, conductive members made of metal plates may be bonded to the first electrodes 411. In another example, the semiconductor device may additionally include electrodes electrically connected to the first electrode 411 via conduction paths formed within the first semiconductor element 41, and the first wires 51 or other conductive members are placed in contact with the additional electrodes.

The bonding part 511 of each first wire 51 is bonded to the first electrode 411 of the first semiconductor element 41 and is what is referred to as the first bond.

The locations of the bonding parts 511 are not specifically limited. In the present embodiment, the bonding parts 511 are formed at dispersed locations within the portion of the first electrode 411 extending out from the first object 2 as viewed in the z direction.

The bonding part 512 of each first wire 51 is bonded to one of the leads 11, 12 and 13. The bonding part 512 is what is referred to as the second bond.

The loop part 513 of each first wire 51 is a curved portion connecting the bonding parts 511 and 512.

In the illustrated example, the bonding parts 511 are located on either side of the first object 2 in the x direction.

The second wires 52 provide electrical connections between the electrodes 421 of the second semiconductor element 42 and the leads 14. The material of the second wires 52 is not specifically limited. For example, the second wires 52 are made of a metal, typically Au, Cu or Al. Each second wire 52 includes a bonding part 521, a bonding part 522 and a loop part 523. The configuration of the second wires 52 is not specifically limited. In the illustrated example, the second wires 52 are formed by using a capillary, for example. In the present embodiment, the second wires 52 conduct the current of a control signal for controlling the first semiconductor element 41 and the second semiconductor element 42.

The bonding part 521 of each second wire 52 is bonded to an electrode 421 of the second semiconductor element 42. The bonding part 521 is what is referred to as the first bond. The bonding part 522 of each second wire 52 is bonded to a lead 14. The bonding part 522 is what is referred to as the second bond.

The loop part 523 of each second wire 52 is a curved portion connecting the bonding parts 521 and 522.

The third wires 53 provide electrical connections between the third electrodes 413 of the first semiconductor element 41 and the electrodes 422 of the second semiconductor element 42. The material of the third wires 53 is not specifically limited. For example, the third wires 53 are made of a metal, typically Au, Cu or Al.

The covering part 7 is interposed between the first electrode 411 and the first object 2. The covering part 7 contains a material having a higher thermal conductivity than the sealing resin 8. The material of the covering part 7 is not specifically limited. When the sealing resin 8 is made of an insulating resin material, the covering part 7 may contain a metal. The metal contained in the covering part 7 may be Ag or Cu, for example. In addition, the covering part 7 may contain sintered Ag or sintered Cu. For the covering part 7 containing sintered Ag, it is preferable to use Ag that can be sintered without the application of pressure. When Ag of a pressureless sintering type is used, the covering part 7 can be formed by discharging a material paste of Ag of a pressureless sintering type from a nozzle, followed by heating the thus applied material paste.

The covering part 7 containing a metal is a non-limited example. In an alternative example, the covering part 7 may contain a resin that is more thermally conductive than the insulating resin forming the sealing resin 8. When the sealing resin 8 is made of an epoxy resin, examples of resins that can be used for forming the covering part 7 include an epoxy resin and an acrylic resin each mixed with a filler for improving the thermal conductivity. When the sealing resin 8 contains a filler, a resin with a higher filler content than that of the sealing resin 8 can be used for the covering part 7.

In this example, the covering part 7 contains sintered Ag, and is in contact with both the first electrode 411 and the second surface 2b (the metal layer 22) of the first object 2. As viewed in the z direction, the covering part 7 is disposed in the region surrounded by the outer edge of the first object 2 (the insulating layer 21). Note, however, that the covering part 7 may have a portion extending out from the first object 2 as viewed in the z direction. In the present embodiment, the covering part 7 is spaced apart from the bonding parts 511 of the first wires 51.

The sealing resin 8 covers a portion of each lead 1, the first semiconductor element 41, the first object 2, the first wires 51, the second wires 52, the third wires 53 and the covering part 7. The sealing resin 8 is made of an insulating resin, which may be an epoxy resin mixed with a filler, for example.

The shape of the sealing resin 8 is not specifically limited. In the illustrated example, the sealing resin 8 has a resin obverse surface 81, a resin reverse surface 82, two first resin side surfaces 83 and two second resin side surfaces 84.

The resin obverse surface 81 faces in the first sense of the z direction and may be a flat surface, for example. The resin reverse surface 82 faces away from the resin obverse surface 81 in the z direction and may be a flat surface, for example.

The two first resin side surfaces 83 are located between the resin obverse surface 81 and the resin reverse surface 82 in the z direction, and face away from each other in the x direction. The two second resin side surfaces 84 are located between the resin obverse surface 81 and the resin reverse surface 82 in the z direction, and face away from each other in the y direction.

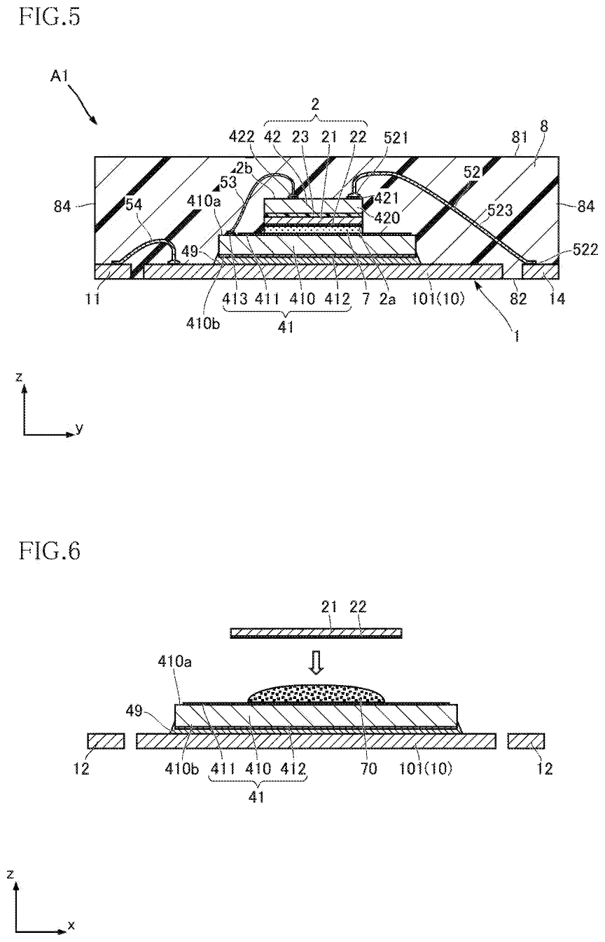

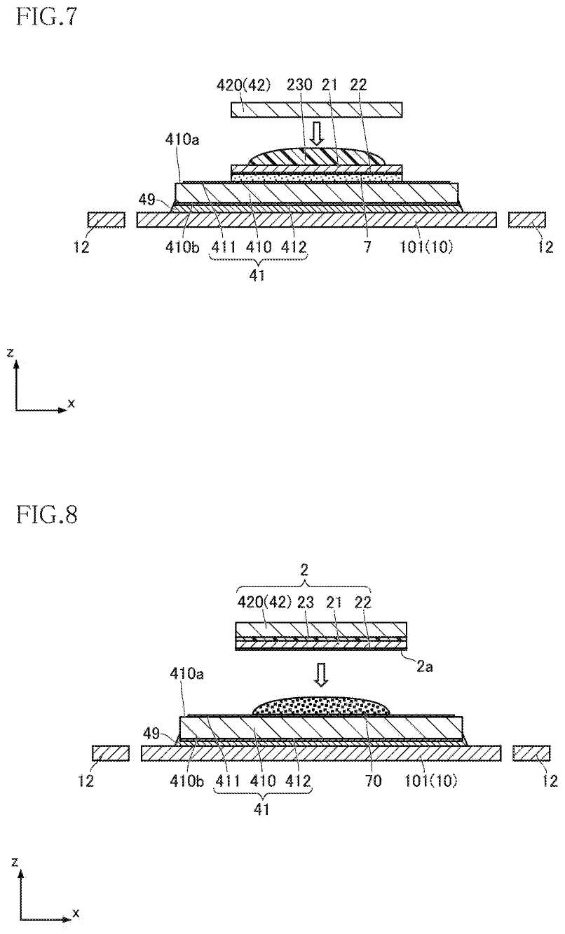

FIGS. 6 and 7 show an example of a method of manufacturing the semiconductor device A1. FIG. 6 shows the first semiconductor element 41 attached to the die pad 101 with the bonding material 49. It also shows a sintering paste 70 applied to the first electrode 411 of the first semiconductor element 41. The sintering paste 70 is not specifically limited. For the covering part 7 containing sintered Ag, the sintering paste 70 that can form sintered Ag by pressureless sintering may be used. The sintering paste 70 can be applied to the first electrode 411 by ejecting the paste from the nozzle of a dispenser, for example. At this stage, the sintering paste 70 thus applied has a shape bulging in the z direction.

Next, the insulating layer 21 having the metal layer 22 is placed into contact with the sintering paste 70. This causes the lower surface of the metal layer 22 in the z direction (the surface that will form the second surface 2b described above) to spread the sintering paste 70. As a result, the sintering paste 70 applied in the shape bulging is in the z direction is flatted and formed into a flat layer having a uniform thickness. Then, a sintering process is performed to obtain the covering part 7 as shown in FIG. 7.

Next, a bonding material 230 is applied to the insulating layer 21. The bonding material 230 is a material that can be hardened to form a bonding layer 23 through a predetermined hardening process, such as an insulating adhesive. Next, the second semiconductor element 42 is brought into contact with the bonding material 230 applied. Then, the bonding material 230 is hardened through the predetermined hardening process to form the bonding layer 23. Here, a variety of hardening processes can be used, such as drying, heating, and ultraviolet radiation. In this way, the bonding layer 23 bonds the second semiconductor element 42 and the insulating layer 21. As a result, the above-described first object 2 composed of the second semiconductor element 42, the bonding layer 23, the insulating layer 21 and the metal layer 22 is obtained.

Subsequently, bonding of the first wires 51, the second wires 52 and the third wires 53 are performed, and the sealing resin 8 is formed. Through these processes, the semiconductor device A1 described above is obtained.

FIG. 8 shows another example of a method of manufacturing the semiconductor device A1. In this example, the insulating layer 21 and the second semiconductor element 42 are bonded in advance by the bonding layer 23. That is, the first object 2 including the second semiconductor element 42, the bonding layer 23, the insulating layer 21 and the metal layer 22 is fabricated in advance. Then, the sintering paste 70 is applied to the first electrode 411, and the first object 2 is placed to bring the first surface 2a (one surface of the metal layer 22) into contact with the thus applied sintering paste 70. Then, similarly to the example shown in FIGS. 6 and 7, the sintering paste 70 is sintered to form the covering part 7.

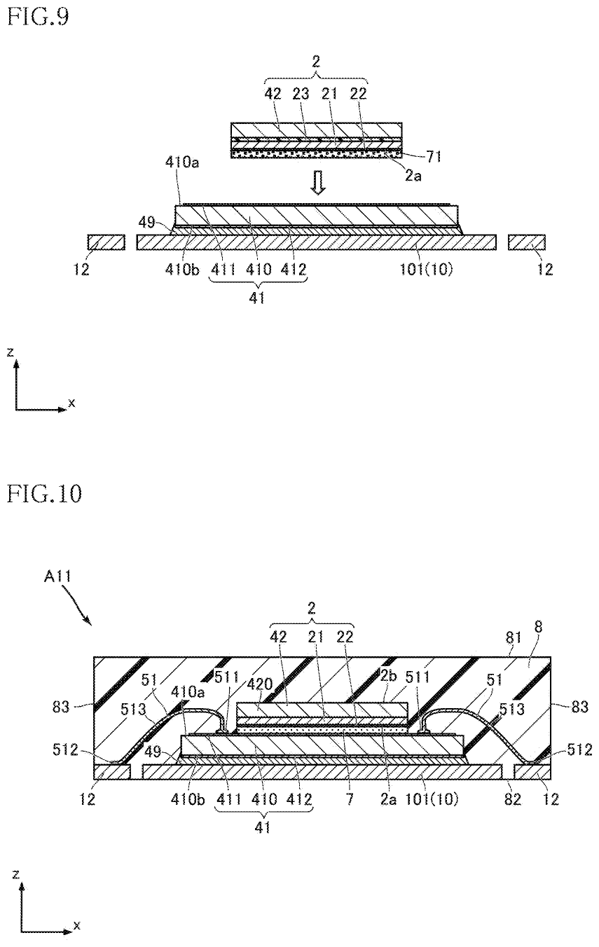

FIG. 9 shows yet another example of a method of manufacturing the semiconductor device A1. In this example, a dried sintering paste 71 is provided in advance to the first object 2 that includes the second semiconductor element 42, the bonding layer 23, the insulating layer 21 and the metal layer 22. The dried sintering paste 71 adheres to the first surface 2a of the first object 2 (the one surface of the metal layer 22). The dried sintering paste 71 may be made of the sintering paste 70 that is hardened by drying, for example. Note, however, that the dried sintering paste 71 is not as fully hardened as the sintering paste 70 that is formed into the covering part 7. The dried sintering paste 71 has been hardened just enough to remain attached to the first surface 2a without deforming even if the dried sintering paste 71 is held downward in the gravitational direction.

The first object 2 having the dried sintering paste 71 is moved downward to place the dried sintering paste 71 into contact with the first electrode 411. Then, the dried sintering paste 71 is sintered, so that the semiconductor device A1 described above is obtained.

The following describes the operation and effect of the semiconductor device A1.

During the operation of the first semiconductor element 41, at least a portion of the energy generated by the electromotive force resulting from the turn-off of the current is converted into heat. If the heat remains in the first semiconductor element 41, the temperature of the first semiconductor element 41 can be excessively high. The semiconductor device A1 includes the covering part 7 interposed between the first electrode 411 and the sealing resin 8. The covering part 7 contains a more thermally conductive material than the sealing resin 8. This promotes transfer of heat from the first electrode 411 to the covering part 7, thereby reducing an excessive temperature rise of the first semiconductor element 41. In addition, the covering part 7 is interposed between the first electrode 411 and the first object 2. This arrangement makes it easier to form the covering part 7 that covers a greater region of the first electrode 411 with a more uniform thickness. The semiconductor device A1 is therefore capable of increasing the amount of energy that can be absorbed by active clamping.

The insulating layer 21 of the first object 2 contains a material that is more thermally conductive than the sealing resin 8. This helps to further increase the amount of energy that can be absorbed by active clamping. In the process of forming the covering part 7, in addition, the sintering paste 70 is spread by the first surface 2a of the first object 2 to a greater region of the first electrode 411. The covering part 7 formed in this way can cover a greater region with a more uniform thickness.

The covering part 7 may contain a metal, in which case transfer of heat from the first electrode 401 can be further improved. Selecting Ag or Cu as the metal contained in the covering part 7 can further improve the thermal conductivity of the covering part 7.

The first surface 2a of the first object 2 is a flat plane extending along the x-y plane. This is preferable for spreading the sintering paste 70 to a greater region with a more uniform thickness.

The first object 2 includes the second semiconductor element 42. The second semiconductor element 42 functions to control the operation of the first semiconductor element 41. This can improve the functionality of the semiconductor device A1. In addition, since the first semiconductor element 41 and the second semiconductor element 42 are separate elements, their materials and thicknesses can be selected to be suitable for the respective elements.

The first object 2 includes the bonding layer 23. The bonding layer 23 is interposed between the second semiconductor element 42 and the covering part 7. This provides more reliable insulation between the first electrode 411 and the second semiconductor element 42. When thermal runaway or other conditions of the second semiconductor element 42 caused by heat is a concern, the bonding layer 23 having a low thermal conductivity can be selected to reduce the possibility.

The first object 2 includes the insulating layer 21. The insulating layer 21 is interposed between the second semiconductor element 42 and the first electrode 411 of the second semiconductor element 42. This provides more reliable insulation between the first electrode 411 and the second semiconductor element 42, which is advantageous when the second semiconductor element 42 is a switching element and the first electrode 411 is a source electrode, and thus a high voltage may be applied to them.

The insulating layer 21 includes the metal layer 22 forming the first surface 2a. This serves to increase the strength of bonding between the first object 2 and the covering part 7.

FIGS. 10 to 27 show other embodiments (or variations) of the present disclosure. In these figures, the same or similar elements as those of the above embodiment are denoted by the same reference signs.

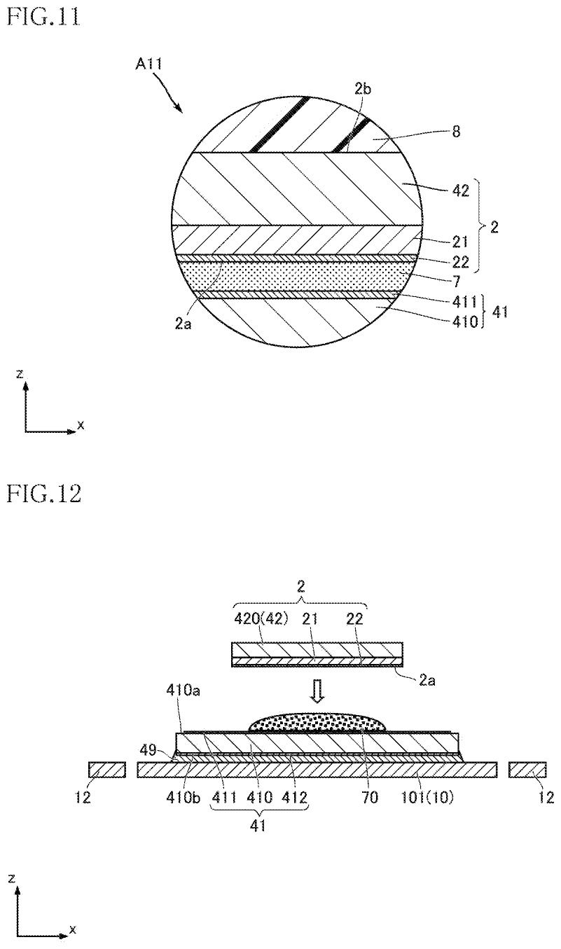

FIGS. 10 and 11 show a first variation of the semiconductor device A1. A semiconductor device A11 of this variation differs from the semiconductor device A1 in the configuration of the first object 2.

In the semiconductor device A11, the first object 2 includes the second semiconductor element 42, the insulating layer 21 and the metal layer 22. That is, the first object 2 of this variation does not include the bonding layer 23 described above. Thus, the second semiconductor element 42 and the insulating layer 21 are in direct contact. The first object 2 of this variation can be obtained by forming the second semiconductor element 42 by conducting semiconductor fabrication processes on the insulating layer 21 containing a ceramic material or Si.

FIG. 12 shows an example of a method of manufacturing the semiconductor device A11. As in the example shown in FIG. 9, the method of this example uses the first object 2 that is fabricated in advance. The first surface 2a (one surface of the metal layer 22) of the first object 2 is placed in contact with the sintering paste 70 applied to the first electrode 411, and then sintering is performed. As a result, the semiconductor device A11 is obtained. Note that the method of this variation can also use the process of applying the dried sintering paste 71 to the first surface 2a of the first object 2 in advance as in the example shown in FIG. 8.

The configuration of this variation enables more energy to be absorbed by active clamping. In addition, since the first object 2 does not include the bonding layer 23, the heat conducted from the first electrode 411 to the covering part 7 can be efficiently transferred to the second semiconductor element 42 via the insulating layer 21. When thermal runaway or other conditions of the second semiconductor element 42 is not a particular concern, the second semiconductor element 42 can be configured to absorb a greater amount of energy.

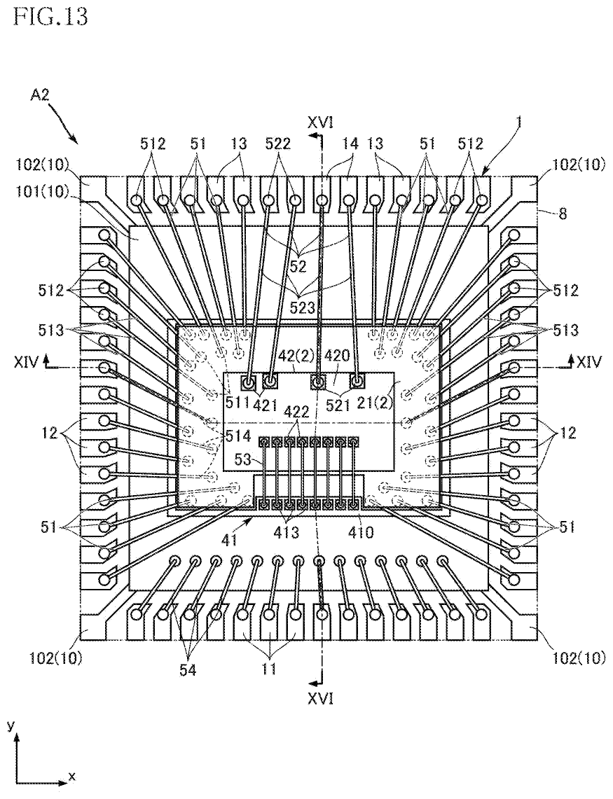

FIGS. 13 to 16 show a semiconductor device according to a second embodiment of the present disclosure. A semiconductor device A2 according to the present embodiment differs from the above-described embodiment mainly in the configurations of the first object 2, the first wires 51 and the covering part 7.

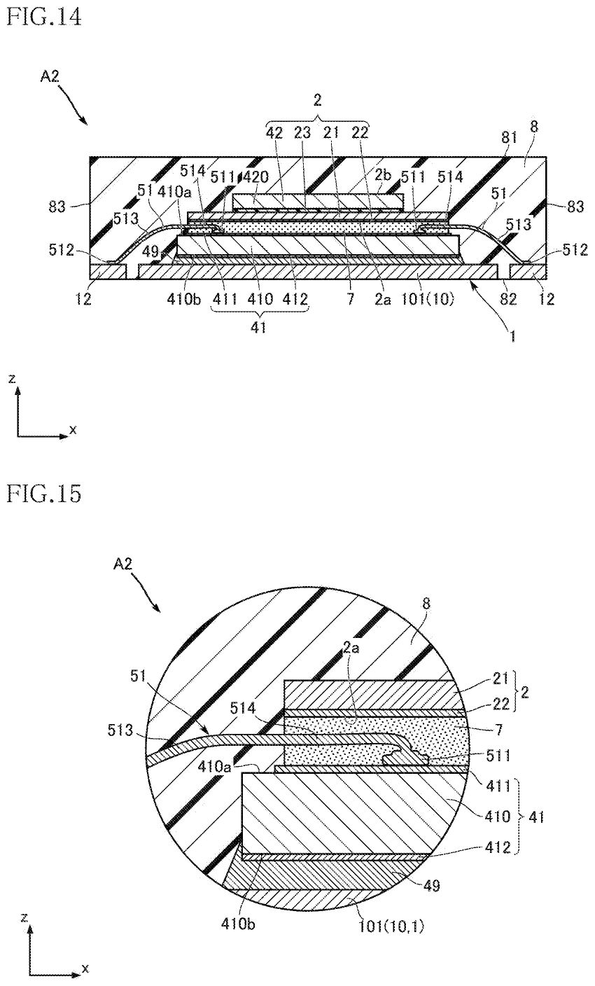

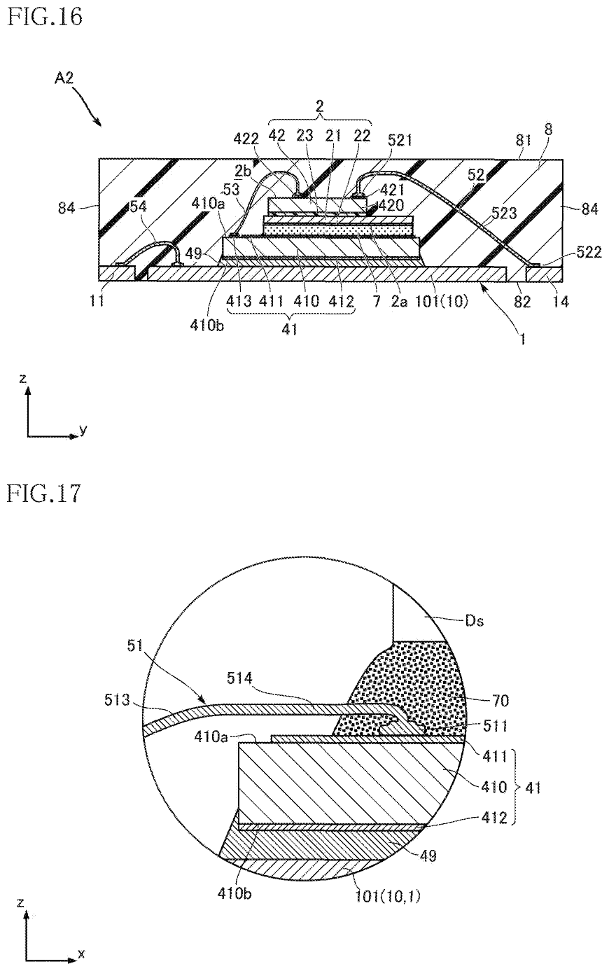

FIG. 13 is a fragmentary plan view of the semiconductor device A2. FIG. 14 is a sectional view taken along line XIV-XIV of FIG. 13. FIG. 15 is an enlarged fragmentary sectional view of the semiconductor device A2. FIG. 16 is a sectional view taken along line XVI-XVI of FIG. 13.

Each first wire 51 of the present embodiment includes a bonding part 511 and a bonding part 512, a loop part 513 and a first part 514.

The bonding part 511 is bonded to the first electrode 411 of the first semiconductor element 41 and is what is referred to as a first bond.

The bonding part 512 is bonded to one of the leads 11, 12 and 13. The bonding part 512 is what is referred to as a second bond.

The first part 514 is a part that extends outward from a location inside the first electrode 411 as viewed in the z direction. In the illustrated example, the first part 514 extends from a location inside the first electrode 411 to a location outside the first electrode 411 across the outer edge of the first electrode 411 as viewed in the z direction. The first part 514 extends in parallel (or substantially parallel) to the x-y plane.

In the present embodiment, the first part 514 is integral with the bonding part 511. That is, in the process of forming each first wire 51, the first part 514 is formed as a continuous unbroken portion of the wire having the bonding part 511.

In the present embodiment, the loop part 513 is a curved portion connecting the bonding part 512 and the first part 514.

The specific configuration of each first wire 51 having the first part 514 may be changed in various manners. For example, each first wire 51 may have an upplight portion extending away from the semiconductor element 4 in the z direction between the bonding part 511 and the first part 514. This configuration is preferable when the bonding part 521 is bonded to a portion located higher in the z direction than the first electrode 411.

The first object 2 of the present embodiment includes the second semiconductor element 42, the bonding layer 23, the insulating layer 21 and the metal layer 22. As viewed in the z direction, each of the insulating layer 21 and the metal layer 22 is larger than the second semiconductor element 42 and has a portion extending out from the second semiconductor element 42. In the illustrated example, the outer dimensions of the insulating layer 21 is the same (or substantially same) as those of the first electrode 411. The insulating layer 21 is formed with a recess for accommodating the third electrodes 413. This recess is larger than the recess of the first electrode 411.

As viewed in the z direction, the insulating layer 21 and the metal layer 22 overlap with the bonding parts 511 and the first parts 514 of the first wires 51. That is, the bonding part 511 of each first wire 51 is located between the first electrode 411 and the first object 2 (the insulating layer 21 and the second surface 2b). Similarly, the first part 514 of each first wire 51 is partly located between the first electrode 411 and the first object 2 (the insulating layer 21 and the second surface 2b). In the illustrated example, the bonding parts 511 and the first parts 514 of all of the first wires 51 overlap with the insulating layer 21 as viewed in the z direction. In a different example, however, the bonding parts 511 and the first parts 514 of only some of the first wires 51 may overlap with the insulating layer 21 as viewed in the z direction.

The covering part 7 is interposed between the first electrode 411 and the second surface 2b (one surface of the metal layer 22) and in contact with the second surface 2b of the first electrode 411. In the present embodiment, the covering part 7 covers the bonding part 511 and a portion of the first part 514 of each first wire 51.

As viewed in the z direction, the covering part 7 is attached to the entire surface (or substantially entire surface) of the insulating layer 21 (the second surface 2b). That is, the covering part 7 has a portion extending out from the second semiconductor element 42 as viewed in the z direction.

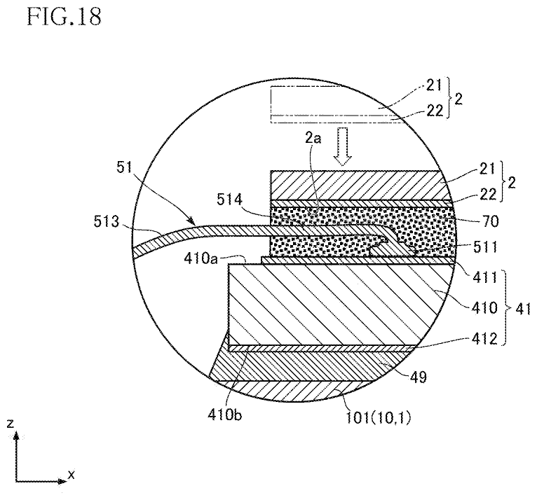

FIGS. 17 and 18 shows an example of a method of manufacturing the semiconductor device A2. FIG. 17 shows the process of applying the sintering paste 70 onto the first electrode 411 of the first semiconductor element 41. The first semiconductor element 41 is electrically bonded in advance to the die pad 101 via the bonding material 49.

The sintering paste 70 is applied by using a dispenser Ds, for example. The sintering paste 70 as applied by the dispenser Ds has a shape bulging in the z direction as in the example shown in FIG. 6. Preferably, the sintering paste 70 thus applied is in contact with the bonding part 511 and the first part 514 of each first wire 51. Since the first part 514 is extends along the x-y plane, it is relatively easy to move the lower end of the dispenser Ds close to the first electrode 411. Note, however, it is not necessary to apply the sintering paste 70 to the entire surface of the first electrode 411. In some examples, the sintering paste 70 may be applied without covering one or more first wires 51 or all of the bonding parts 511.

Next, as shown in FIG. 18, the first surface 2a (one surface of the metal layer 22) of the first object 2 is pressed against the sintering paste 70. As a result, the sintering paste 70 is squeezed and spread between the first electrode 411 and the first surface 2a. As a result, the sintering paste 70 covers the bonding part 511 and a portion of the first part 514 of each first wire 51. Preferably, the first object 2 is pressed against the sintering paste 70 without causing the first surface 2a of the first object 2 to touch the first parts 514 of the first wires 51.

The configuration of the present embodiment enables more energy to be absorbed by active clamping. In the present embodiment, in addition, the covering part 7 has a portion extending out from the second semiconductor element 42 and hence covers a greater region of the first electrode 411. This configuration enables the covering part 7 to absorb an increased amount of energy. In addition, the bonding part 511 of each first wire 51 is located between the first electrode 411 and the first surface 2a of the first object 2 and covered by the covering part 7. This allows the covering part 7 to be disposed to cover a greater region with a more uniform thickness, and enables the covering part 7 to prevent detachment of the bonding parts 511 from the first electrode 411.

Each first wire 51 has the first part 514 connected to the bonding part 511. The first part 514 extends along the x-y plane. With this configuration, the covering part 7 is sandwiched between the first surface 2a of the first object 2 and the first electrode 411, while allowing the first wire 51 to extend without touching the first surface 2a.

The first part 514 is integrally connected to the bonding part 511. Consequently, a relatively sharp bend tends to be formed at the portion where the first part 514 and the bonding part 511 are connected. Thus, the covering part 7 covering this portion serves to protect the first wires 51 more reliably.

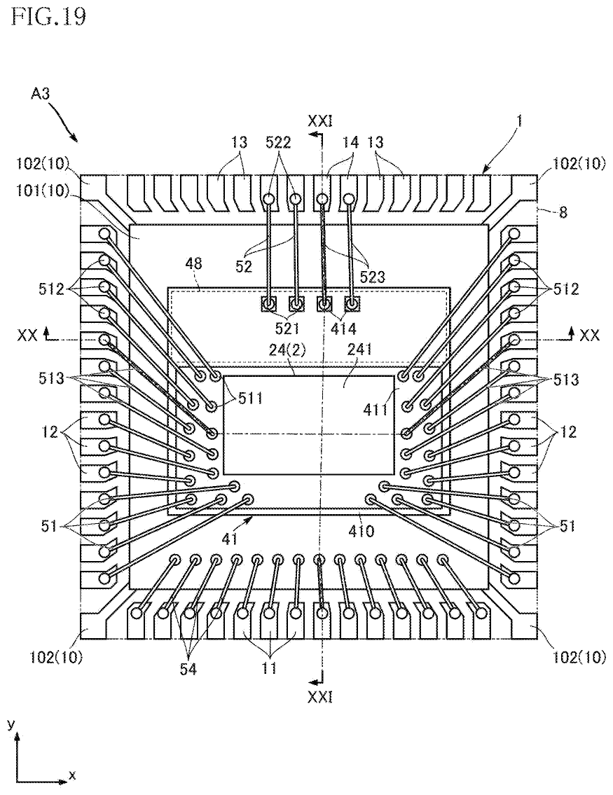

FIGS. 19 to 21 show a semiconductor device according to a third embodiment of the present disclosure. A semiconductor device A3 according to the present embodiment differs from the semiconductor devices of the above-described embodiments mainly in the configurations of the first semiconductor element 41 and the first object 2.

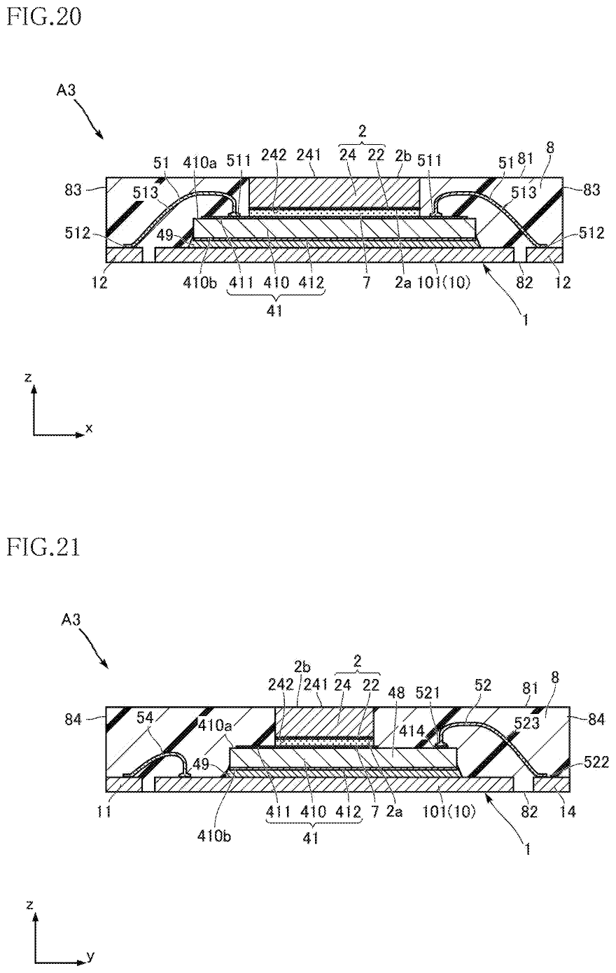

FIG. 19 is a fragmentary plan view of the semiconductor device according to the third embodiment of the present disclosure. FIG. 20 is a sectional view taken along line XX-XX of FIG. 19. FIG. 21 is a sectional view taken along line XXI-XXI of FIG. 19.

The first semiconductor element 41 of the present embodiment includes a control part 48. That is, the semiconductor element 4 includes a portion forming a transistor that performs a switching function and a portion that performs a function of controlling, monitoring and protecting the transistor.

As viewed in the z direction, the control part 48 is offset toward the end of the first semiconductor element 41 in the second sense of the y direction. The functional layer that acts as the transistor is offset toward the end of the first semiconductor element 41 in the first sense of the y direction. The control part 48 and the functional layer are connected by internal wiring (not shown) of the first semiconductor element 41. The first electrode 411 is located in the first sense of the y direction from the control part 48. However, the arrangement and other details of the functional layer 408 and the control part 48 are not specifically limited.

The first semiconductor element 41 includes a plurality of fourth electrodes 414. The fourth electrodes 414 are electrically connected to the control part 48. The functions of the fourth electrodes 414 are not specifically limited, and the fourth electrodes 414 may have similar functions to those of the electrodes 421 included in the second semiconductor element 42 of the semiconductor device A1.

The first object 2 is bonded to the first electrode 411 via the covering part 7. As viewed in the z direction, the first object 2 overlaps with the first electrode 411 and is spaced apart from the control part 48.

The first object 2 of this example includes an insulating member 24 and a metal layer 22. The insulating member 24 is a plate-like member made of a ceramic material, such as alumina or aluminum nitride, or Si, for example. The insulating member 24 has an insulating-member obverse surface 241 and an insulating-member reverse surface 242. The insulating-member reverse surface 242 faces the first electrode 411. The insulating-member obverse surface 241 faces away from the insulating-member reverse surface 242. The insulating-member obverse surface 241 forms the second surface 2b of the first object 2.

In this example, the insulating-member obverse surface 241 is exposed from the sealing resin 8. The insulating-member obverse surface 241 is a flat surface and flush with the resin obverse surface 81.

The metal layer 22 is disposed on the insulating-member reverse surface 242 of the insulating member 24. One surface of the metal layer 22 forms the first surface 2a of the first object 2. The metal layer 22 is in contact with the covering part 7.

In the present embodiment, the first wires 51 electrically connect the first electrode 411 and the leads 11 and 12. The bonding parts 511 of the first wires 51 are bonded to the first electrode 411. The bonding parts 512 of some of the first wires 51 are bonded to the leads 11, and some to the leads 12. The first wires 51 may include one or more wires electrically connecting the first electrode 411 and leads 13.

The second wires 52 electrically connect the fourth electrodes 414 of the first semiconductor element 41 and the leads 14. The bonding parts 521 of the second wires 52 are bonded to the fourth electrodes 414. The bonding parts 522 of the second wires 52 are bonded to the leads 14.

The configuration of the present embodiment enables more energy to be absorbed by active clamping. In addition, the insulating-member obverse surface 241 that is exposed from the sealing resin 8 also serves to increase the amount of energy that can be absorbed by active clamping. In addition, the insulating member 24 containing an insulating material serves to prevent an unintentional electrical connection between the first electrode 411 and an external component via the first object 2.

As can be understood from the present embodiment, various changes can be made to the first object 2 according to the present disclosure.

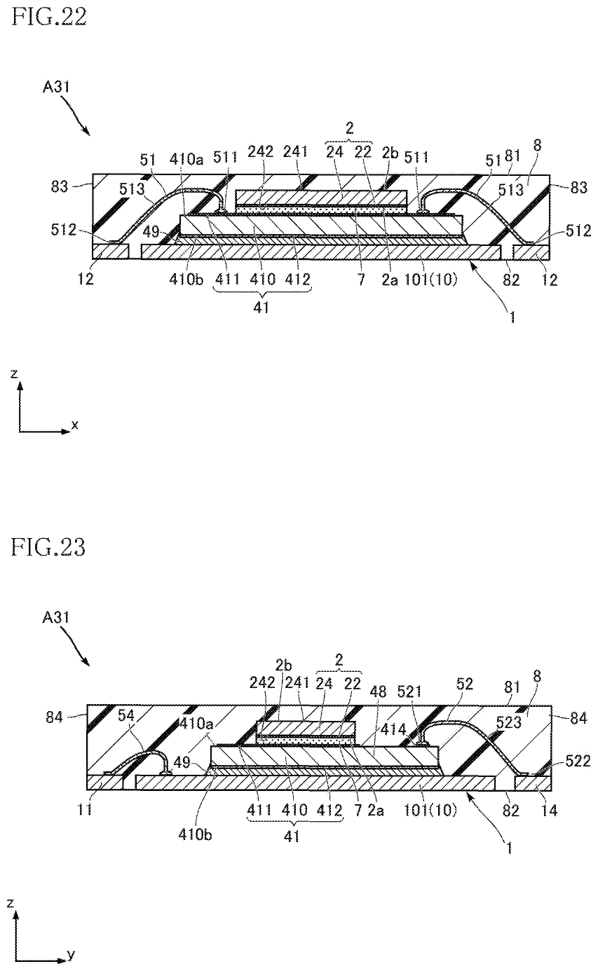

FIGS. 22 and 23 show a first variation of the semiconductor device A3. The semiconductor device A31 of this variation differs from the semiconductor device A3 in the relation between the first object 2 and the sealing resin 8.

In this variation, the insulating-member obverse surface 241 of the insulating member 24 is covered with the sealing resin 8 and not exposed from the sealing resin 8.

The configuration of this variation enables more energy to be absorbed by active clamping. As can be understood from this variation, the insulating-member obverse surface 241 of the insulating member 24 may be covered with the sealing resin 8.

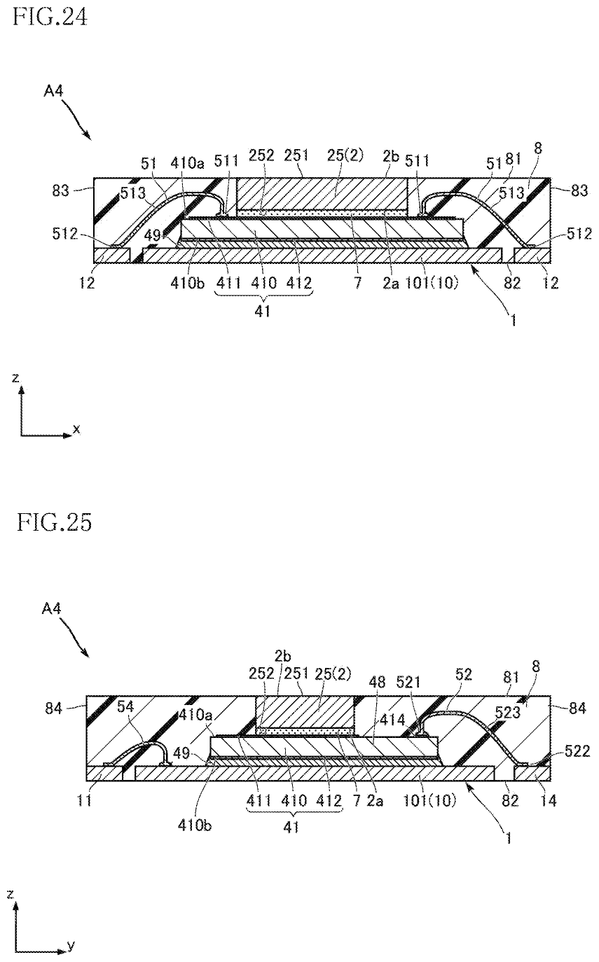

FIGS. 24 and 25 show a semiconductor device according to a fourth embodiment of the present disclosure. A semiconductor device A4 according to the present embodiment differs from the semiconductor devices of the above-described embodiments mainly in the configurations of the first object 2. In plan view, the configuration of the semiconductor device A4 is similar to that of, for example, the semiconductor device A3 shown in FIG. 19.

The first object 2 of the present embodiment includes a metal member 25. The first object 2 of this embodiment is entirely made of the metal member 25. The metal member 25 contains a metal. Examples of the metal for the metal member 25 includes Cu, Fe, Al, Ai and Ag.

The metal member 25 has a metal-member obverse surface 251 and a metal-member reverse surface 252. The metal-member reverse surface 252 faces the first electrode 411. The metal-member obverse surface 251 faces away from the metal-member reverse surface 252. The metal-member obverse surface 251 forms the second surface 2b of the first object 2. The metal-member reverse surface 252 forms the first surface 2a of the first object 2.

In this embodiment, the metal-member obverse surface 251 is exposed from the sealing resin 8. The metal-member obverse surface 251 is a flat surface and flush with the resin obverse surface 81. In the case where the first object 2 is bonded to the first electrode 411 by the covering part 7 that contains a metal, such as sintered Ag, the metal member 25 is electrically connected to the first electrode 411. Then, the metal-member obverse surface 251 can be used as a terminal surface for establishing an electrical connection to an external circuit. In such a case, the metal-member obverse surface 251 may be plated with Sn, for example, to facilitate the process of electrical bonding and other processing.

The configuration of the present embodiment enables more energy to be absorbed by active clamping. In addition, the metal member 25 included in the first object 2 also serves to further increase the amount of energy that can be absorbed by active clamping. The metal-member obverse surface 251 exposed from the sealing resin 8 is desirable for improving dissipation of heat to the outside the semiconductor device A4. In addition, the metal-member obverse surface 251 can be used as a terminal surface of the semiconductor device A4.

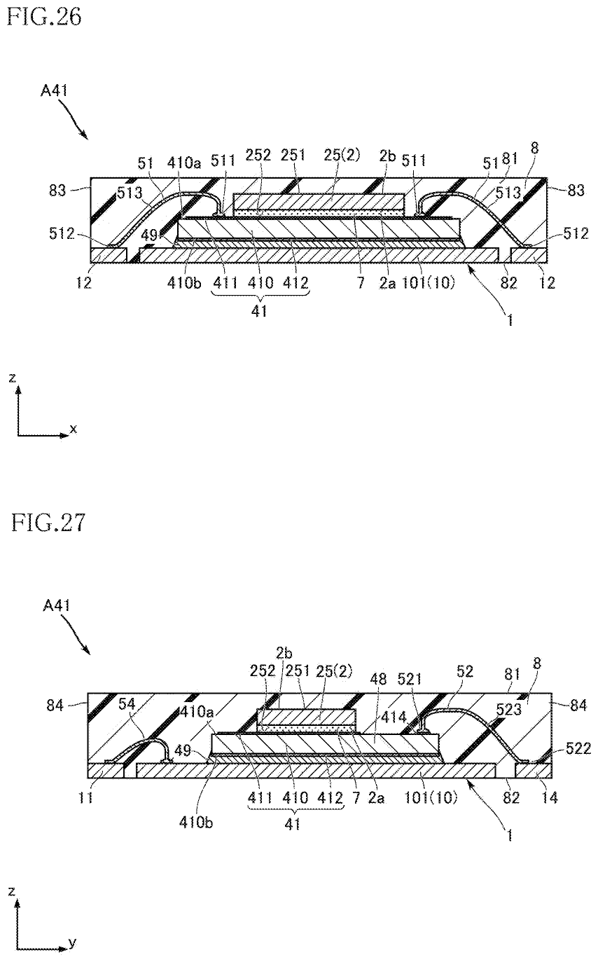

FIGS. 26 and 27 show a first variation of the semiconductor device A4. The semiconductor device A41 of this variation differs from the semiconductor device A4 in the relation between the first object 2 and the sealing resin 8.

In this variation, the metal-member obverse surface 251 of the metal member 25 is covered with the sealing resin 8 and not exposed from the sealing resin 8.

The configuration of this variation enables more energy to be absorbed by active clamping. As can be understood from this variation, the metal-member obverse surface 251 of the metal member 25 may be covered with the sealing resin 8. This configuration serves to prevent an unintentional electrical conduction between the metal member 25 and an external component.

The semiconductor devices according to the present disclosure are not limited to the embodiments described above. Various design changes can be made to the specific configuration of each part of a semiconductor device according to the present disclosure. The present disclosure includes the embodiments described in the following clauses.

Clause 1.

A semiconductor device comprising:
a first semiconductor element including a first electrode;
a first object including a first surface facing the first electrode;
a sealing resin covering the first semiconductor element and the first object; and
a covering part interposed between the first electrode and the first surface and containing a material having a higher thermal conductivity than the sealing resin.

Clause 2.

The semiconductor device according to Clause 1, wherein the covering part contains a metal.

Clause 3.

The semiconductor device according to Clause 2, wherein the covering part contains Ag or Cu.

Clause 4.

The semiconductor device according to Clause 3, wherein the covering part contains sintered Ag or sintered Cu.

Clause 5.

The semiconductor device according to any one of Clauses 1 to 4, wherein the first electrode contains Al.

Clause 6.

The semiconductor device according to any one of Clauses 1 to 5, wherein the first object includes a second semiconductor element.

Clause 7.

The semiconductor device according to Clause 6, wherein the first object includes an insulating layer interposed between the second semiconductor element and the covering part.

Clause 8.

The semiconductor device according to Clause 7, wherein the insulating layer contains a ceramic material or Si.

Clause 9.

The semiconductor device according to any one of Clauses 1 to 5, wherein the first object includes an insulating member.

Clause 10.

The semiconductor device according to Clause 9, wherein the insulating member contains a ceramic material or Si.

Clause 11.

The semiconductor device according to any one of Clauses 1 to 5, wherein the first object includes a conductive member.

Clause 12.

The semiconductor device according to Clause 11, wherein the conductive member contains a metal.

Clause 13.

The semiconductor device according to any one of Clauses 9 to 12, wherein the first object includes a second surface facing away from the first surface and exposed from the sealing resin.

Clause 14.

The semiconductor device according to any one of Clauses 1 to 13, further comprising a first wire including a bonding part bonded to the first electrode.

Clause 15.

The semiconductor device according to Clause 14, wherein the covering part is in contact with the bonding part.

Clause 16.

The semiconductor device according to Clause 15, wherein the bonding part is located between the first electrode and the first object.

Clause 17.

The semiconductor device according to any one of Clauses 1 to 16, wherein the first semiconductor element has a switching function, and
the first electrode is a source electrode.

### REFERENCE NUMERALS

A1, A1, A2, A3, A31, A4, A41: Semiconductor device
1, 10, 11, 12, 13, 14: Lead
2: First object 2a: First surface
2b: Second surface 4: Semiconductor element
7: Covering part 8: Sealing resin
21: Insulating layer 22: Metal layer
23: Bonding layer 24: Insulating member
25: Metal member 41: First semiconductor element
42: Second semiconductor element 48: Control part
49: Bonding material 51: First wire
52: Second wire 53: Third wire
54: Fourth wire 70: Sintering paste
71: Dried sintering paste 81: Resin obverse surface
82: Resin reverse surface 83: First resin side surface
84: Second resin side surface 101: Die pad
102: Corner part 230: Bonding material
241: Insulating-member obverse surface
242: Insulating-member reverse surface
251: Metal-member obverse surface
252: metal-member reverse surface
401: First electrode 408: Functional layer
410: Element body 410a: Element obverse surface
410b: Element reverse surface 411: First electrode
412: Second electrode 413: Third electrode
414: Fourth electrode 420: Element body
421, 422: Electrode
511, 512, 521, 522: Bonding part
513, 523: Loop part 514: First part
Ds: Dispenser

1. A semiconductor device comprising:
a first semiconductor element including a first electrode;
a first object including a first surface facing the first electrode;
a sealing resin covering the first semiconductor element and the first object; and
a covering part interposed between the first electrode and the first surface and containing a material having a higher thermal conductivity than the sealing resin.

2. The semiconductor device according to claim 1, wherein the covering part contains a metal.

3. The semiconductor device according to claim 2, wherein the covering part contains Ag or Cu.

4. The semiconductor device according to claim 3, wherein the covering part contains sintered Ag or sintered Cu.

5. The semiconductor device according to claim 1, wherein the first electrode contains A1.

6. The semiconductor device according to claim 1, wherein the first object includes a second semiconductor element.

7. The semiconductor device according to claim 6, wherein the first object includes an insulating layer interposed between the second semiconductor element and the covering part.

8. The semiconductor device according to claim 7, wherein the insulating layer contains a ceramic material or Si.

9. The semiconductor device according to claim 1, wherein the first object includes an insulating member.

10. The semiconductor device according to claim 9, wherein the insulating member contains a ceramic material or Si.

11. The semiconductor device according to claim 1, wherein the first object includes a conductive member.

12. The semiconductor device according to claim 11, wherein the conductive member contains a metal.

13. The semiconductor device according to claim 9, wherein the first object includes a second surface facing away from the first surface and exposed from the sealing resin.

14. The semiconductor device according to claim 1, further comprising a first wire including a bonding part bonded to the first electrode.

15. The semiconductor device according to claim 14, wherein the covering part is in contact with the bonding part.

16. The semiconductor device according to claim 15, wherein the bonding part is located between the first electrode and the first object.

17. The semiconductor device according to claim 1, wherein the first semiconductor element has a switching function, and the first electrode is a source electrode.
